(19) United States
(12) Patent Application Publication
(10) Pub. No.: US 2021/0195792 A1
(43) Pub. Date: Jun. 24, 2021

(54) SYSTEM FOR CONTROLLING A COOLING UNIT OF A TRANSFORMER

(71) Applicant: SIEMENS AKTIENGESELLSCHAFT, MUENCHEN (DE)

(72) Inventors: AIME MBUY, NUERNBERG-WEIHERHAUS (DE); BERTHOLD SEDLMAIER, ROETHENBACH A.D. PEGNITZ (DE); TOBIAS ENGLMANN, FREYSTADT (DE)

(21) Appl. No.: 17/056,497

(22) PCT Filed: Apr. 18, 2019
(86) PCT No.: PCT/EP2019/060053

§ 371 Date: Nov. 18, 2020

(30) Foreign Application Priority Data
May 18, 2018 (DE) 10 2018 207 846.7

(51) Int. Cl. H05K 7/20; H01F 27/08; G05B 15/02; B61C 3/00; B61C 17/00; B60L 15/00

(52) U.S. Cl. CPC H05K 7/20209; H05K 7/20863; H01F 27/08; B60L 2200/26; B61C 3/00; B61C 17/00; B60L 15/00; G05B 15/02

(57) ABSTRACT

A system for controlling a cooling unit of a transformer, more particularly a traction transformer of a rail vehicle, improves the efficiency and lifespan of the transformer having the cooling unit. The system includes a transformer, a cooling unit configured to cool the transformer, and a control unit configured to control the cooling unit for cooling the transformer. The control unit is configured to control the cooling unit using measurement data representing at least one condition of the system and/or using environmental data in anticipation of a change in the temperature of the transformer based on the utilization of the transformer and/or environmental influences. This prevents the transformer from overheating, thereby increasing the efficiency and lifespan of the transformer. A corresponding method for controlling a system is also provided.

The present invention relates to a system for controlling a cooling unit of a transformer, in particular a traction transformer of a rail vehicle. The invention further relates to a method for controlling a system.

Transformers, in particular traction transformers of rail vehicles, are often subject to fluctuating loads owing to the time-variable power reduction on the consumer side. In the case of a traction transformer of a rail vehicle, fluctuations of this type occur in particular as a result of different drive power required by the rail car, fluctuating utilization of the vehicle air conditioning, vehicle lighting, etc.

However, the efficiency of a transformer decreases in the case of high temperatures of the transformer, since, amongst other things, the electrical resistance of the windings increases with the temperature. A higher portion of the electrical energy is therefore lost by being converted into heat. Furthermore, the lifespan of a transformer reduces regularly if certain temperature thresholds are exceeded.

This problem is significantly greater in built-in traction transformers of rail vehicles than in free-standing transformers because the former are more difficult to cool owing to greater structural limitations. An active cooling is regularly required above a certain converted power via a cooling unit, in order to dissipate the heat generated by power loss and to prevent overheating.

However, a cooling unit which is associated with the transformer has its own energy consumption and should therefore not be permanently in operation under full load, for the sake of efficiency. Instead, the cooling unit is regulated in a power-specific manner and is adjusted precisely to the required power. An improvement in the efficiency of the transformer and a lower energy consumption of the cooling system is therefore achieved overall. However, owing to the unavoidable temporal delay until a full cooling action of the cooling unit comes into effect, temporary overheating in the full load operation of the transformer does still sometimes occur, for example in a traction transformer, if a rail vehicle strongly accelerates.

The underlying object of the invention involves improving the efficiency and lifespan of a transformer including the cooling unit.

According to the invention, this object is achieved in a system mentioned at the outset by the system comprising the following:
a transformer
a cooling unit which is set up to cool the transformer,
a control unit which is set up to regulate the cooling unit for cooling the transformer,
   wherein the control unit is set up to regulate the cooling unit using measurement data representing at least one condition of the system and/or environmental data in anticipation of a changing temperature of the transformer based on the utilization of the transformer and/or based on environmental influences.

The control unit therefore turns up the cooling unit, for example, before an increase in the load of the transformer occurs, and/or turns it down before a reduction in the load of the transformer occurs. The control unit can accelerate or slow down the speed of a pump for this purpose, for example. On the one hand, this can prevent the transformer from overheating, since in the event of a sudden peak load, the transformer is already precooled as a precaution. On the other hand, the cooling unit can already be turned down if the control unit expects that the load of the transformer will decrease in the near future, for example if a route segment with a low speed lies ahead or a final stop is soon to be reached. With this solution, the control unit therefore effectively “knows” before a power is required that it must activate the cooling unit at a specific point in time in order to cool down the transformer in a timely manner. By means of the targeted cooling, there are lower losses in the transformer and the efficiency of the transformer is thus increased, i.e. less power is consumed. In addition, the lifespan of the transformer is increased, since exceeding the temperature tolerances can be prevented. The measurement data preferably describe at least one condition of the system. The measurement data are preferably condition data measured in the system, for example temperature data.

It is possible to use this solution for new transformer systems and to incorporate it into existing transformer systems. The installation of this adaptability either takes place in new transformer systems directly during production or by way of an add-on kit which can also be used in any traction transformer of a rail vehicle. This means that every older transformer can also be upgraded, irrespective of the producer. This technical solution makes it possible for the system to adapt to the respective environmental conditions, save energy and increase the lifespan of the transformer.

Within the framework of this application, measurement data of the condition of the system can be measurement data of the condition of the transformer and/or the cooling unit, for example. However, other measurement data, for example from other parts of the rail vehicle, can also be included.

Regulating the cooling of the transformer can be realized by regulating a motor and/or a pump and/or a fan and/or the oil flow, for example.

In one embodiment, the system has at least one sensor which is connected to the control unit, wherein the at least one sensor
comprises a temperature sensor arranged on the transformer,
a temperature sensor arranged in a coolant line between the transformer and cooling unit and/or
a mass flow sensor arranged in a coolant line between the transformer and cooling unit.

The control unit is provided with more measurement data with one or a plurality of sensors, on the basis of which measurement data the cooling unit can be regulated in a more targeted manner. The control unit can therefore also readjust the cooling unit in real time, for example if the desired cooling of the transformer is not working quickly enough or more quickly than expected. For example, the cooling power of the cooling unit can decrease with the age of the system and as a reaction the system can turn the cooling unit up higher, in order to compensate for this. On the other hand, an unexpected additional power change in the transformer or environmental influences can also cause the temperature of the transformer or the coolant to fall more quickly or more slowly than expected and, as a reaction to this, the system can readjust the cooling unit. A temperature sensor can be a PT100 temperature probe, for example. A temperature sensor arranged on the transformer can preferably be arranged on the outside of a vessel of the transformer.

New transformers can additionally also use optical sensors for measuring the temperature, which optical sensors measure the flow of the coolant (e.g. oil) in the coolant line, for example. At the same time, a flow regulator can also be installed in the cooling circuit which variably regulates the flow of the coolant (rate, capacity/min.). This can be realized by a pair of mutually displaceable bulkhead plates, whereby coolant passages are enlarged/reduced by the bulkhead plates. A flow regulator of this type often enables a quicker and more targeted changing of the cooling action than merely readjusting a pump motor in the cooling circuit, for example.

In one embodiment, the measurement data comprise at least one of the following:
a temperature of the transformer,
a temperature of a coolant provided by the cooling unit,
a mass flow of the coolant provided by the cooling unit,
a power of a pump motor in the cooling circuit of the cooling unit,
a power of at least one fan of the cooling unit.

Each of the aforementioned measurement data improves the condition measurement and therefore the predictive capability of the system. By means of the aforementioned measurement data, the control unit can readjust the cooling unit in real time. If the desired cooling of the transformer is not working quickly enough or more quickly than expected, the control unit can react and readjust and thus prevent undercooling or overcooling, for example. The system can therefore also react to deviations of the expected power reduction and temperature development in an intelligent manner.

Furthermore, the measurement data preferably comprise measured data on a temperature of the transformer, measured data on a temperature of a coolant provided by the cooling unit, measured data on a mass flow of the coolant provided by the cooling unit, measured data on a pump power of the cooling unit and/or measured data on a power of a fan of the cooling unit.

In one embodiment, the environmental data comprise at least one of the following:
topographical information regarding a route, in particular of a rail vehicle which comprises the transformer,
a load profile of the route,
route, course of the route,
local weather data,
location data of the transformer,
information from other transformers, in particular from other rail vehicles, and the environmental data thereof.

Furthermore, the environmental data preferably comprise data on topographical information regarding a route, in particular of a rail vehicle which comprises the transformer, data on a load profile of the route, local weather data and/or location data of the transformer.

Environmental data are of great importance in order to carry out as precise a prediction as possible of the expected load of the transformer by way of the system. Environmental data can comprise the following, for example:
information regarding the route of the train: topographical data of the route, such as altitude and gradient, maximum speed and/or load profiles of the route, neighborhoods or densely built-up sections with (time-dependent) speed limits;
weather data, preferably detailed along the route;
location of the transformer in real time, for example via GPS data.

The more different environmental data made available to the system at any given time, the more precisely the condition of the transformer can be predicted and thus the cooling power of the cooling unit regulated. For example, the cooling power can be turned up or turned down in a timely manner in accordance with the expected speed of the rail vehicle along the route. Similarly, if a high outside temperature is expected, a generally increased cooling requirement can be predicted by the cooling unit and the cooling unit can be regulated by the system accordingly.

In one embodiment, the system comprises a database, preferably a cloud database, and a data connection between the control unit and the database, wherein the system is set up in such a way that the measurement data representing the at least one condition are sent to the database via the data connection, and/or the system is set up in such a way that the environmental data are stored in the database and the control unit retrieves the environmental data via the data connection. Alternatively or additionally, the system can also comprise a local database, for example as part of the control unit. It is also possible that a plurality of systems according to the invention are connected to a central database in each case via, preferably wireless data connections. In particular, environmental data can be usefully centrally stored. However, a local database of the system can also regularly download, for example, the environmental data which is relevant for the current route and store it locally, for example in the control unit, in order to still have a set of environmental data available even if the data connection fails.

The measurement data collected locally at the transformer and/or the cooling unit can be stored in the local database and/or in the cloud database. The measurement data can also be initially stored in the local database and then be transmitted into the cloud database.

The data connection can take place via a mobile network and/or rail vehicle internal communication, for example, such as Wi-Fi, Bluetooth or WLAN, for example. Both the unprocessed sensor data (mass data) and/or condition data processed by a processing unit of the control unit can be transmitted via the data connection. The processing unit can be an ASIC processor or preferably a processor on which a firmware has been installed, for example.

In one embodiment, the system comprises prediction algorithm software, wherein the prediction algorithm software is set up to determine, by means of a mathematical model using the measurement data representing the at least one condition and/or the environmental data (weather data, topographical data, etc.), so that a changing temperature of the transformer based on a predicted utilization of the transformer and/or based on predicted environmental influences is to be expected at a subsequent point in time. In this embodiment, the control unit receives the “knowledge” regarding the point in time at which, the duration for which and the intensity at which the cooling process should take place by way of the cooling unit from prediction algorithm software, i.e. a so called “smart algorithm”, for example. Prediction algorithm software of this type can use one or a plurality of the following, for example: Monte Carlo algorithm, Travelling Salesman algorithm, neural networks or an evolutionary algorithm.

In one embodiment, the prediction algorithm software is run in a cloud database and connected to the control unit via a data connection. It is also possible that parts of the prediction algorithm software are run in a local database, for example inside the rail vehicle, and another part of the prediction algorithm software is run in a cloud database. Depending on the scope of the prediction algorithm software and the required computing power and storage capacity, it can be advantageous to run part of or all of the prediction calculations non-locally, i.e. in a cloud database, for example. This limits the computer hardware which is required locally, in particular in the case of a rail vehicle. Furthermore, prediction algorithm software in a cloud database has the advantage that it can also be connected to a plurality of systems and can “learn” from these systems. Over the course of time, the prediction algorithm software can therefore analyze, from the collected data, how the required cooling power is dependent on the age and type of the respective system, in particular the transformer and the cooling unit, and can incorporate this information in future predictions for the respective system.

The data sets from measurement data of the condition of the system and/or from environmental data can therefore be processed by prediction algorithm software. A set of instructions can then be sent to the control unit as a result. The control unit then regulates the cooling unit in accordance with the instructions.

The object according to the invention is also achieved by a method for controlling a system, comprising:
a transformer,
a cooling unit which is set up to cool the transformer,
a control unit which is set up to regulate the cooling unit for cooling the transformer,
   wherein the control unit regulates the cooling unit in anticipation of a changing temperature of the transformer based on the utilization of the transformer and/or based on environmental influences. The cooling unit can therefore be turned up, for example, before an increase in the load of the transformer occurs, and/or turned down before a reduction in the load of the transformer occurs. This method makes it possible to prevent the transformer from overheating, since in the event of a sudden peak load, the transformer is already precooled as a precaution. Similarly, the cooling unit can already be turned down if the control unit expects that the load of the transformer will decrease in the near future, for example if a route segment with a lower load profile lies ahead or a final stop is soon to be reached. According to the method, it is therefore forecasted that a higher power is needed at a later point in time and that the cooling unit must be activated at an earlier point in time in order to cool down the transformer in a timely manner. By means of the targeted cooling, lower losses are generated in the transformer. This means that the efficiency of the transformer is increased, i.e. less electrical energy is lost owing to heat losses. In addition, the lifespan of the transformer is increased, since exceeding the temperature tolerances can be prevented.

It is possible to use this solution for new transformer systems and to incorporate it into existing transformer systems. The installation of this adaptability either takes place in new transformers directly during production or by way of an add-on kit which can also be used in any traction transformer of a rail vehicle. The method according to the invention can also be used in an older system as a “stand alone” via a new control software of the control unit, for example.

The more measurement data on the condition of the system and regulation possibilities that are available for the cooling unit, the more efficient the method according to the invention can be. For this reason, it can also be useful to upgrade an older system with one or a plurality of sensors, for example.

This technical solution enables the method to adapt the cooling of the transformer to the respective environmental and operational conditions, to save energy and to increase the lifespan of the transformer.

In one embodiment, the system comprises prediction algorithm software,
wherein the prediction algorithm software calculates, by means of a mathematical model using measurement data representing at least one condition of the system and/or environmental data, that a changed temperature of the transformer based on a predicted utilization of the transformer and/or based on predicted environmental influences is to be expected at a subsequent point in time,
wherein the prediction algorithm software sends instructions for regulating the cooling unit to the control unit based on the calculated expectation.

The prediction algorithm software can be run in a local database of the system and/or in a cloud database. Prediction algorithm software in a cloud database has the advantage that it can also be connected to a plurality of systems according to the invention and can “learn” from all of these systems. Over the course of time, the prediction algorithm software can thus analyze, from the collected data, how the required cooling power is dependent on the age and type of the respective system (in particular the transformer and the cooling unit) and can incorporate this information in future predictions for the respective system.

According to the method, data sets from measurement data of the condition of the system and/or from environmental data can be processed by prediction algorithm software. A set of instructions can then be sent to the control unit from the prediction algorithm software as a result. The control unit then regulates the cooling unit in accordance with the set of instructions.

In one embodiment, the system, preferably the prediction algorithm software, uses at least one of the following measurement data for calculating the expectation of a changing temperature of the transformer:
a temperature of the transformer,
a temperature of a coolant provided by the cooling unit,
a mass flow of the coolant provided by the cooling unit,
a power of a pump motor in the cooling circuit,
a power of at least one fan of the cooling unit
   and/or at least one of the following environmental data:
topographical information regarding a route, in particular of a rail vehicle comprising the transformer,
a load profile of the route,
local weather data,
location data of the transformer,
journey time according to the timetable.

The more different measurement data on the condition of the system and/or environmental data made available at any given time, the more precisely the condition of the transformer can be predicted with the method and thus the cooling power of the cooling unit adjusted. For example, according to the method, the cooling power can be turned up or turned down in a timely manner in accordance with the expected speed of the rail vehicle along the route. Similarly, if a high outside temperature is expected, a generally increased cooling requirement can be predicted by the cooling unit and the cooling unit can be regulated by the method accordingly.

All of the features described in relation to the system according to the invention are also claimed in relation to the method according to the invention, and vice versa.

The characteristics, features and advantages of this invention as well as the manner in which they are achieved become clearer and more comprehensible in the context of the following description of the exemplary embodiments, which are explained in greater detail in the context of the drawings. In the drawings:

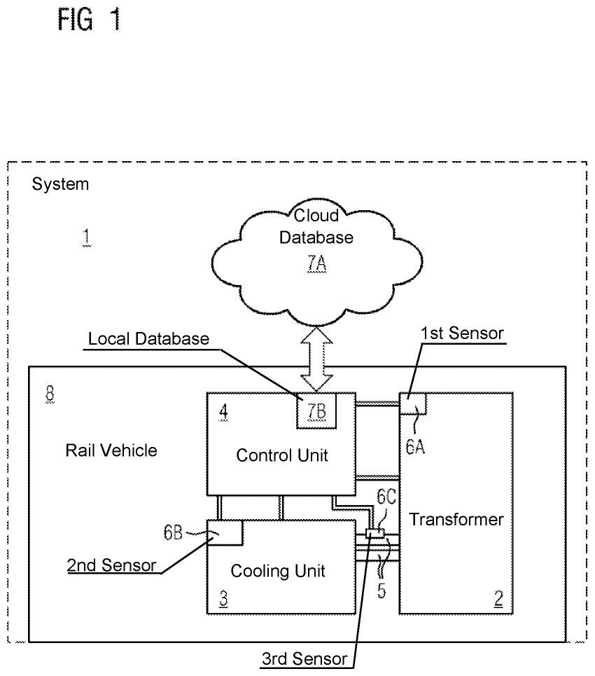

FIG. 1 shows a schematic design of an exemplary embodiment of a system according to the invention,

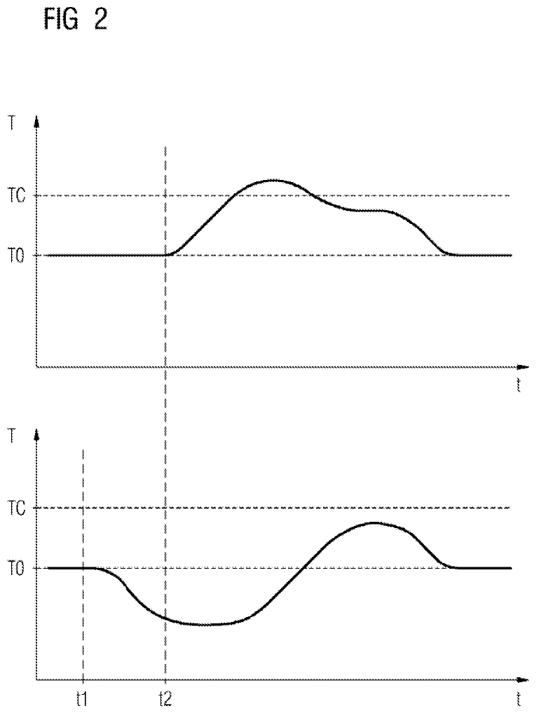

FIG. 2 shows a comparison of exemplary temperature curves of a transformer of a system of the prior art compared to a transformer of a system according to the invention, and

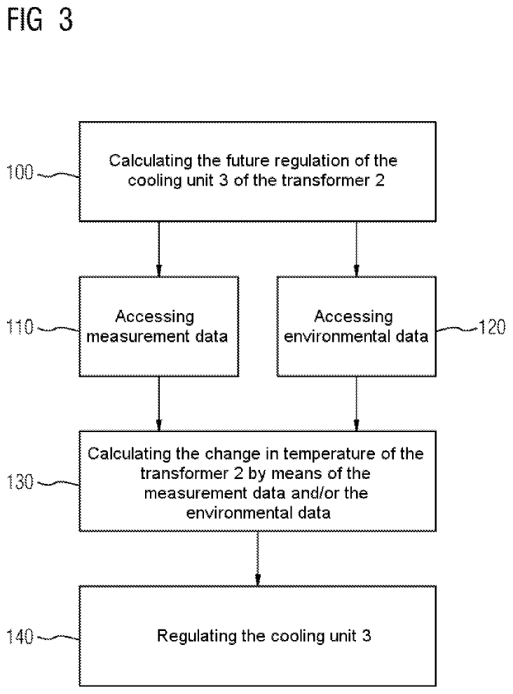

FIG. 3 shows an exemplary embodiment of a method according to the invention in a flowchart.

FIG. 1 shows a system 1 according to the invention, comprising a transformer 2, a cooling unit 3 and a control unit 4. The cooling unit 3 is set up to cool the transformer 2 and is connected to the transformer 2 via coolant lines 5 for this purpose. The cooling unit 3 can comprise one or a plurality of further elements which are not represented for the sake of clarity, such as a fan and/or a pump and/or a motor, for example.

The control unit 4 is set up to regulate the cooling unit 3 for cooling the transformer 2. In particular, the control unit 4 is set up to regulate the cooling unit 3 based on measurement data of the condition of the system 1 and/or on environmental data in anticipation of a changing temperature of the transformer 2 based on the utilization of the transformer 2 and/or based on environmental influences. For this purpose, the system comprises sensors 6A, 6B, 6C which are connected to the control unit 4, in order to supply the control unit 4 with measurement data on the condition of the system 1. The measurement data of the sensors 6A, 6B, 6C can transmit the measurement data to the control unit 4 in a wired or wireless manner (for example via Wi-Fi, Bluetooth, WLAN or mobile networks). The indicated cable connections between the sensors 6A, 6B, 6C and the control unit 4 are therefore merely to be understood as exemplary.

In this exemplary embodiment, a first sensor 6A is arranged on the transformer 2. This sensor 6A can be a temperature sensor, for example, which supplies the control unit 4 with temperature data of the transformer 2. However, the system 1 can also comprise a plurality of sensors 6A on the transformer 2, for example further temperature sensors and/or current or voltage measuring devices for determining the outputted power on the consumer side of the transformer 2.

In this embodiment, a second sensor 6B is arranged on the cooling unit 3. This sensor 6B can measure a pump power of a pump of the cooling unit 3 or a power of a fan of the cooling unit 3 and send it to the control unit 4, for example.

A third sensor 6C is arranged in or on one of the coolant lines 5. This sensor 6C can be a temperature sensor for measuring the temperature of the coolant and/or a flow sensor for measuring the mass flow of the coolant provided by the cooling unit 3, for example.

Alternatively or additionally, a flow regulator can also be arranged at the position of the sensor 6C, which flow regulator regulates the flow of coolant to or from the transformer 2. The flow regulator can preferably be regulated by the control unit 4.

In this example, the system 1 also comprises two databases 7A, 7B. The first database 7A is a cloud database which is connected to the control unit 4 via a data connection. The database 7B is a local database, i.e. a hard drive and/or a main memory of the control unit 4, for example. The system 1 can be set up in such a way that the measurement data of the condition of the transformer 2 are sent to one or both databases 7A, 7B via the data connection. The system 1 can also be set up in such a way that environmental data can be stored in one or both databases 7A, 7B, and the control unit 4 can retrieve the environmental data via a data connection.

The system 1 preferably comprises prediction algorithm software which is set up to determine, by means of a mathematical model based on measurement data of the condition of the transformer 2 and/or on environmental data, that a changing temperature of the transformer 2 based on a predicted utilization of the transformer 2 and/or based on predicted environmental influences is to be expected at a subsequent point in time.

The prediction algorithm software can be run in the cloud database 7A and connected to the control unit 4 via a data connection. However, parts of or the entire prediction algorithm software can also be run in a local database 7B.

However, depending on the required computing power of the prediction algorithm software, it may be useful not to run the more complex calculations locally, in order to limit the computer hardware which is required in the control unit 4. In particular, if the prediction algorithm software is adaptive and is connected to a plurality of systems and transformers, it is preferable if the prediction algorithm software is run in the cloud database 7A and can access historical data sets from different systems according to the invention there, for example.

In the present embodiment, the transformer 2 is a traction transformer of a rail vehicle 8 in which the cooling unit 3 and the control unit 4 are also arranged. However, the system 1 can also, in principle, be used for other transformers with a fluctuating load.

Environmental data are topographical information regarding a route, in particular of the rail vehicle 8 comprising the transformer 2, a load profile of the route, local weather data or location data of the transformer 2, for example. The system 1 can comprise a GPS unit for this purpose, for example, in order to determine the location of the transformer 2 in real time.

FIG. 2 shows an exemplary curve of the temperature T of a transformer of the prior art in the top part of the figure and an exemplary curve of the temperature T of a transformer 2 in a system 1 of the present invention in the bottom part of the figure.

T0 specifies a normal operating temperature of the transformer 2, at which the transformer is not or only slightly loaded, for example. TC specifies a critical temperature of the transformer 2, above which the efficiency of the transformer decreases rapidly and the lifespan of the transformer 2 is reduced. It is desirable to avoid exceeding the temperature TC as far as possible.

At the point in time t2, a heavy load of the transformer begins in both parts of the figure, for example in a rail vehicle, as a result of a strong acceleration. In a transformer of the prior art, the cooling unit is only activated when the heavy load occurs. However, it takes a certain amount of time until the full cooling action of the cooling unit is achieved, and the transformer therefore temporarily exceeds the critical temperature TC until the cooling unit can cool down the transformer to an acceptable temperature below the critical temperature TC. Exceeding the critical temperature TC causes heat losses of the transformer to increase significantly and the lifespan to be reduced.

In the case of the system 1 according to the invention, at the point in time t1, before the beginning of the heavy load of the transformer 2 at the point in time t2, the cooling unit 3 is already activated by the control unit 4 in anticipation of the subsequent heavy load. In the case of a rail vehicle 8, the control unit 4 can “know” that a route segment with a high speed is imminent, for example, therefore a heavy load of the transformer 2 is to be expected, and can turn up the cooling unit 3 ahead of time. This can prevent the critical temperature TC from being exceeded in many or even all cases and the efficiency and lifespan of the transformer 2 can be increased.

FIG. 3 shows an exemplary embodiment of a method according to the invention in a flowchart. In one step 100, the future regulation of the cooling unit 3 of the transformer 2 is calculated by the control unit 4 and/or prediction algorithm software. In one step 110, measurement data are accessed for this purpose. Alternatively or additionally, in one step 120, environmental data on the external conditions of the transformer 2 are accessed. In one step 130, the change in temperature of the transformer 2 based on the utilization of the transformer 2 and/or based on environmental influences is calculated by means of the measurement data and/or the environmental data. In one step 140, the cooling unit 3 is then turned up by the control unit 4 before an increase in the load of the transformer 2 occurs and/or turned down before a reduction in the load of the transformer 2 occurs. This method makes it possible to prevent most, if not all, cases of exceeding a safe operating temperature of the transformer 2 and to thus to increase the efficiency and lifespan of the transformer 2. A “schedule” can also be created for the cooling unit 3 depending on the time, track position, etc. The “schedule” can also be revised on a regular basis, in order to be able to react to unexpected changes in the measurement data or the environmental data, for example in the weather or as a result of delays during driving operation.

Although the invention has been illustrated and described in greater detail by preferred exemplary embodiments, the invention is not limited by the disclosed examples and other variations can be derived from this by the person skilled in the art, without departing from the scope of protection of the invention.

### LIST OF REFERENCE SYMBOLS

1 system
2 transformer
3 cooling unit
4 control unit
5 coolant line
6A sensor
6B sensor
6C sensor
7A database (cloud database)
7B database (local database)
8 rail vehicle
100 step
110 step
120 step
130 step
140 step
T temperature
T0 normal operating temperature
TC critical temperature
T0 normal operating temperature
t time
t1, t2 point in time

1-10. (canceled)

11. A system, comprising:
a transformer or a traction transformer of a rail vehicle;
a cooling unit configured to cool said transformer; and
a control unit configured to regulate said cooling unit for cooling said transformer;
said control unit regulating said cooling unit by using measurement data representing at least one of at least one condition of the system or environmental data in anticipation of a changing temperature of the transformer based on at least one of utilization of said transformer or environmental influences.

12. The system according to claim 11, which further comprises at least one sensor connected to said control unit, said at least one sensor including at least one of:
a temperature sensor disposed on said transformer,
a temperature sensor disposed in a coolant line between said transformer and said cooling unit, or
a mass flow sensor disposed in a coolant line between said transformer and said cooling unit.

13. The system according to claim 11, wherein the measurement data includes at least one of:
a temperature of said transformer,
a temperature of a coolant provided by said cooling unit,
a mass flow of a coolant provided by said cooling unit,
a power of a pump motor in a cooling circuit of said cooling unit, or
a power of at least one fan of said cooling unit.

14. The system according to claim 11, wherein the environmental data include at least one of:
topographical information regarding a route or a route of a rail vehicle having said transformer,
a load profile of a route,
a course of a route,
local weather data,
location data of said transformer, or
information from other transformers or from other rail vehicles and environmental data of the other transformers or other rail vehicles.

15. The system according to claim 11, which further comprises:
a database or a cloud database; and
a data connection between said control unit and said database;
said data connection configured to at least one of:
send the measurement data representing the at least one condition to said database, or
send the environmental data stored in said database to said control unit.

16. The system according to claim 11, which further comprises prediction algorithm software, said prediction algorithm software configured to determine, by utilizing a mathematical model using the measurement data representing at least one of the at least one condition or the environmental data, that a changing temperature of said transformer, based on at least one of a predicted utilization of said transformer or predicted environmental influences, is to be expected at a subsequent point in time.

17. The system according to claim 16, wherein said prediction algorithm software is run in a cloud database and is connected to said control unit by a data connection.

18. A method for controlling a system, the method comprising:
providing a transformer;
using a cooling unit to cool the transformer;
providing a control unit for regulating the cooling unit for cooling the transformer; and
using the control unit to regulate the cooling unit in anticipation of a changing temperature of the transformer based on at least one of a utilization of the transformer or environmental influences.

19. The method according to claim 18, which further comprises:
using prediction algorithm software to calculate, by utilizing a mathematical model using measurement data representing at least one of at least one condition of the system or environmental data, that a changed temperature of the transformer based on at least one of a predicted utilization of the transformer or predicted environmental influences is to be expected at a subsequent point in time; and
using the prediction algorithm software to send instructions for regulating the cooling unit to the control unit based on the calculated expectation.

20. The method according to claim 18, wherein the system or the prediction algorithm software uses at least one of:
at least one measurement data for calculating an expectation of a changing temperature of the transformer selected from a group including:
a temperature of the transformer,
a temperature of a coolant provided by the cooling unit,
a mass flow of a coolant provided by the cooling unit,
a power of a pump motor in a cooling circuit of the cooling unit,
a power of at least one fan of the cooling unit, or
at least one environmental data selected from a group including:
topographical information regarding a route or a route of a rail vehicle having the transformer,
a load profile of a route,
local weather data,
location data of the transformer, or
journey time according to a timetable.
